(19) United States
(12) Patent Application Publication
(10) Pub. No.: US 2007/0200179 A1
(43) Pub. Date: Aug. 30, 2007

(54) Strain enhanced CMOS architecture with amorphous carbon film and fabrication method of forming the same

(75) Inventor: Cheng-Ku Chen, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/360,683

(22) Filed: Feb. 24, 2006

(51) Int. Cl. H01L 29/94; H01L 21/8238

(52) U.S. Cl. 257/369; 438/199; 257/382; 438/300; 257/E27.062

(57) ABSTRACT

A strain enhanced CMOS device using amorphous carbon films and fabrication methods of forming the same. The amorphous carbon (a-C) film, such as fluorinated amorphous carbon (a-C:F), is formed of a tensile film or a compressive film to act a stress capping film on the pMOS device region or the nMOS device region. The amorphous carbon film also acts a contact etching stop layer during a contact hole etching process.

### TECHNICAL FIELD

The present invention relates to CMOS devices in integrated circuit manufacturing processes, and more particularly to strain enhanced CMOS devices using amorphous carbon films and fabrication methods of forming the same.

### BACKGROUND

A principal factor in maintaining adequate performance in field effect transistors (FETs) is carrier mobility that affects the amount of current or charge in a doped semiconductor channel under control of a voltage placed on a gate electrode insulated from the channel by a very thin dielectric. Reduced carrier mobility in an FET reduces not only the switching speed of a given transistor but also the difference between “on” resistance and “off” resistance. Particularly, in the development of complementary metal-oxide-semiconductor (CMOS) field effect transistors, carrier mobility is a design concern. One problem facing CMOS manufacturing is that nMOS and pMOS devices require different types of stress in order to achieve increased carrier mobility.

Currently, the CMOS manufacturing techniques selectively address pMOS and nMOS devices. A pMOS fabrication method includes using substrate structures that apply a compression stress to the channel, and an nMOS fabrication method includes using a tensile film to improve carrier mobility. In one approach, using selective epitaxial SiGe in silicon recesses of the source and drain regions, longitudinal uniaxial compressive stress is introduced into the pMOS device to increase hole mobility. Also, using a tensile SiN capping layer on the gate structure, tensile strain is introduced into the nMOS device to enhance electron mobility. In the embedded SiGe source/drain approach, the SiGe profile in the silicon recess is critical for strain profile which impacts device performance greatly. However, the embedded SiGe process needs extra lithography, etching, hard mask film deposition and clean process, causing high process costs. Also, it is difficult to control the etching depth and the silicon recess profile since the recess etching process is a time-mode control without using an etching stop layer, thereby consuming heavy cost on process monitor. In addition, the tensile SiN capping layer, also serving as a contact etching stop layer (CESL), will be consumed by about 200 Angstroms and have poor uniformity in subsequent contact hole etching step by the use of dry strip on photoresist and BARC with O₂/H₂ and CF₄ flow gas, high power, significant ion bombardment and over-etch time control. A subsequent step for removing the CESL, a plasma process with an over-etch time control further causes significant loss of silicide and/or oxides on the contact bottom and/or at shallow trench isolation (STI) edge. The weak spots on the thinner silicide or the junction at the STI edge cause defects of shorts and/or high junction leakage, imposing severe limitations in forming shallow junctions.

In another approach, tensile and compressive SiN capping layers are prepared to induce tensile strain and compressive strain in nMOS/pMOS channel regions respectively. In detailed, after silicidation process, a compressive SiN film with a thin buffer oxide layer are provided and then selectively removed from the nMOS device region. Similarly, a tensile SiN film with a thin buffer oxide layer are provided and then selectively removed from the pMOS device region. The buffer oxide layer is needed for acting an etching stop layer during the steps of removing the SiN films on specified MOS regions so as to prevent etching through the source/drain regions, the gate, and the sidewall spacers. Each of the compressive SiN films and the tensile SiN film also acts a CESL. The SiN film, however, is a high-k dielectric material that may result in capacitive coupling noise between adjacent voltage transients. Since the CESL is close to gate oxide and the SiN film usually contains high level of hydrogen, transistors reliability performance (e.g. hot carriers lifetime, negative bias temperature instability (NBTI), . . . etc.) is disadvantageously degraded. In addition to those problems in the contact hole etching process as discussed above, since the etching rate between the tensile and compressive SiN films is different, more significant contact over-etch is required, which causes more loss of silicide and/or oxides and worsens junction leakage.

It is therefore desirable to provide strain enhanced CMOS devices and fabrication methods for preventing the conventional problems from the use of SiN stress capping layers.

### SUMMARY OF THE INVENTION

Embodiments of the present invention include strain enhanced CMOS devices using amorphous carbon films and fabrication methods of forming the same. The amorphous carbon (a-C) film, such as fluorinated amorphous carbon (a-C:F), is formed of a tensile film or a compressive film to act a stress capping film on a pMOS device region and/or an nMOS device region. The amorphous carbon film also acts a contact etching stop layer during a contact hole etching process.

In one aspect, the present invention provides a semiconductor device that has a pMOS device region and an nMOS device region defined on a semiconductor substrate. A first gate structure is overlying the pMOS device region and a second gate structure is overlying the nMOS device region. Each of the first gate structure and the second gate structure has a gate electrode overlying the semiconductor substrate and a source/drain region in the semiconductor substrate laterally adjacent to the gate electrode. Silicide regions are on the gate electrodes and the source/drain regions of the first gate structure and the second gate structure respectively. An amorphous carbon film with tensile stress is formed overlying the first gate structure, the second gate structure and the silicide regions. A dielectric layer is formed overlying the amorphous carbon film and has contact holes passing through the dielectric layer and the amorphous carbon film to expose the silicide regions on the source/drain regions of the first gate structure and the second gate structure respectively.

In another aspect, the present invention provides a semiconductor device having a pMOS device region and an NMOS device region defined on a semiconductor substrate. A first gate structure is overlying the pMOS device region and a second gate structure is overlying the nMOS device region. Each of the first gate structure and the second gate structure has a gate electrode overlying the semiconductor substrate and a source/drain region in the semiconductor substrate laterally adjacent to the gate electrode. Silicide regions are on the gate electrodes and the source/drain regions of the first gate structure and the second gate structure respectively. A first amorphous carbon film with compressive stress is formed overlying the first gate structure and the silicide regions on the pMOS device region. A second amorphous carbon film with tensile stress is formed overlying the second gate structure and the silicide regions on the nMOS device region. A dielectric layer is formed overlying the first amorphous carbon film and the second amorphous carbon film and comprising contact holes passing through the dielectric layer, the first amorphous carbon film and the second amorphous carbon film to expose the silicide regions on the source/drain regions of the first gate structure and the second gate structure respectively.

In another aspect, the present invention provides a method of forming a semiconductor device. A semiconductor substrate is provided with a pMOS device region and an nMOS device region. A first gate structure is formed overlying the pMOS device region, and a second gate structure is formed overlying the nMOS device region. Each of the first gate structure and the second gate structure has a gate electrode overlying the semiconductor substrate and a source/drain region in the semiconductor substrate laterally adjacent to the gate electrode. Silicide regions are formed on the gate electrodes and the source/drain regions of the first gate structure and the second gate structure respectively. An amorphous carbon film with tensile stress is formed on the semiconductor substrate to cover the first gate structure, the second gate structure and the silicide regions. A dielectric layer is formed overlying the amorphous carbon film. Contact holes are formed to pass through the dielectric layer and the amorphous carbon film to expose the silicide regions on the source/drain regions of the first gate structure and the second gate structure respectively.

In another aspect, the present invention provides a method of forming a semiconductor device. A semiconductor substrate is provided with a pMOS device region and an nMOS device region. A first gate structure is formed overlying the pMOS device region, and a second gate structure is formed overlying the nMOS device region. Each of the first gate structure and the second gate structure has a gate electrode overlying the semiconductor substrate and a source/drain region in the semiconductor substrate laterally adjacent to the gate electrode. Silicide regions are formed on the gate electrodes and the source/drain regions of the first gate structure and the second gate structure respectively. A first amorphous carbon film with compressive stress is formed to cover the first gate structure and the silicide region on the pMOS device region. A second amorphous carbon film with tensile stress is formed to cover the second gate structure and the silicide region on the nMOS device region. A dielectric layer is formed overlying the first amorphous carbon film and the second amorphous carbon film. Contact holes are formed to pass through the dielectric layer, the first amorphous carbon film and the second amorphous carbon film to expose the silicide regions on the source/drain regions of the first gate structure and the second gate structure respectively.

In another aspect, the present invention provides a method of forming a semiconductor device. A semiconductor substrate is provided with a pMOS device region and an nMOS device region. A first gate structure is formed overlying the pMOS device region, and a second gate structure is formed overlying the nMOS device region. Each of the first gate structure and the second gate structure has a gate electrode overlying the semiconductor substrate and a source/drain region in the semiconductor substrate laterally adjacent to the gate electrode. A first amorphous carbon film with tensile stress is formed to cover the second gate structure on the nMOS device region. An activation anneal process is performed to achieve tensile stress in a channel of the second gate structure. After removing the first amorphous carbon film, silicide regions are formed on the exposed portions of the gate electrodes and the source/drain regions of the first gate structure and the second gate structure respectively. A second amorphous carbon film with tensile stress is formed on the semiconductor substrate to cover the first gate structure, the second gate structure and the silicide regions. A dielectric layer is formed overlying the second amorphous carbon film. Contact holes are formed to pass through the dielectric layer and the second amorphous carbon film to expose the silicide regions on the source/drain regions of the first gate structure and the second gate structure respectively.

### BRIEF DESCRIPTION OF THE DRAWINGS

The aforementioned objects, features and advantages of this invention will become apparent by referring to the following detailed description of the preferred embodiments with reference to the accompanying drawings, wherein:

FIGS. 1A to 1D are cross-sectional diagrams illustrating an exemplary embodiment of a method of forming a strain enhanced CMOS architecture using a tensile amorphous carbon film;

FIGS. 2A to 2G are cross-sectional diagrams illustrating an exemplary embodiment of a method of forming a strain enhanced CMOS architecture using amorphous carbon films as a tensile stress capping film and a compressive stress capping film on the nMOS device and the pMOS device respectively; and

FIGS. 3A to 3E are cross-sectional diagrams illustrating an exemplary embodiment of a method of forming a strain enhanced CMOS architecture using amorphous carbon films as an activation capping film and a tensile stress capping film on the nMOS device.

### DETAILED DESCRIPTION OF ILLUSTRATIVE EMBODIMENTS

Embodiments of the present invention provide strain enhanced CMOS devices using amorphous carbon films and fabrication methods of forming the same, which overcome the aforementioned problems of the prior art through the use of SiN capping films. The amorphous carbon (a-C) film, such as a fluorinated amorphous carbon (a-C:F) film, is a low-temperature deposition material formed by chemical vapor deposition (CVD) or physical vapor deposition (PVD). The amorphous carbon film has low dielectric constant. For example, a-C:F has a k value less than 2.8. Depending on deposition conditions (e.g., power, temperature, and the like), the amorphous carbon film may be formed of a tensile film or a compressive film to act a stress capping film that may be selectively formed on a pMOS device region and/or an nMOS device region. The amorphous carbon film may also act a contact etching stop layer (CESL) because of its good selectivity to oxide, nitride and silicide, thus the problems caused by the etching rate difference existed between capping stress films on the NMOS device region and the pMOS device region respectively are overcome, the loss of silicide and/or oxide is prevented during the contact hole etching process, and the conventional use of buffer oxide layers is unnecessary. This can introduce strained-silicon on the channel regions of the CMOS device by a simple and low cost process flow. For stress memorization technique (SMT) applications, the amorphous carbon film is easily to be stripped by dry ash with high selectivity to the underlying layer. In addition, the amorphous carbon film contains no hydrogen therein, which enlarges etching process window and makes subsequent contact etching flow become a simple and fully in-situ process.

The embodiments of the present invention benefit advanced CMOS transistor in 65 nm generations and beyond. In the manufacturing aspect, the amorphous carbon film simplifies strained Si process and has process costs much lower than conventional methods of using SiGe process and SiN capping layers. The contact hole etching steps are also reduced because of simultaneous stripping of photoresist, BARC and CESL within one chamber. The final scheme offers the enhancement of productivity and process control with great precision. In the process integration aspect, compared with the conventional use of SiN capping films, the amorphous carbon film serving as the stress capping layer and the contact etch stop layer has advantages of low temperature deposition, good selectivity to underlying layers (such as oxide and silicide), good thermal stability, facilitation in stripping, tunable stress, and low dielectric constant (such as k value less than 2.8). In the transistor design aspect, the inventive scheme provides shallower junction due to negligible loss of silicide and/or oxide. In the device or product reliability aspect, the hydrogen-free property of the amorphous carbon film (e.g., a-C:F) certainly assures high reliability performance in hot carrier and negative bias temperature instability (NBTI) of CMOS transistors.

Reference will now be made in detail to the present embodiments, examples of which are illustrated in the accompanying drawings. Wherever possible, the same reference numbers are used in the drawings and the description to refer to the same or like parts. In the drawings, the shape and thickness of one embodiment may be exaggerated for clarity and convenience. This description will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be present.

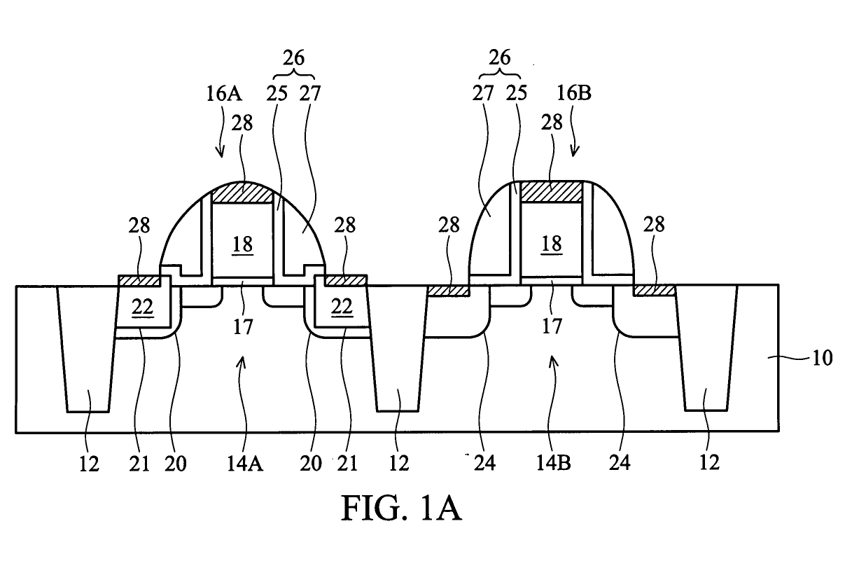

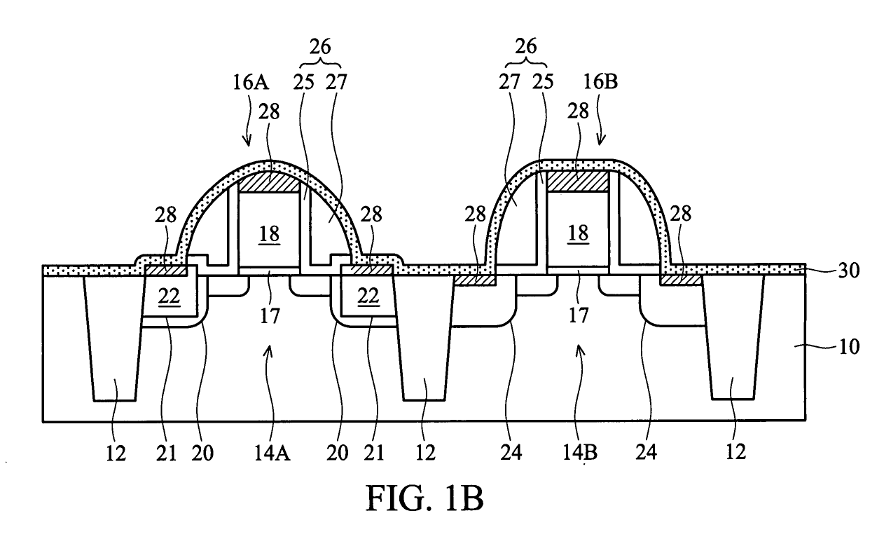

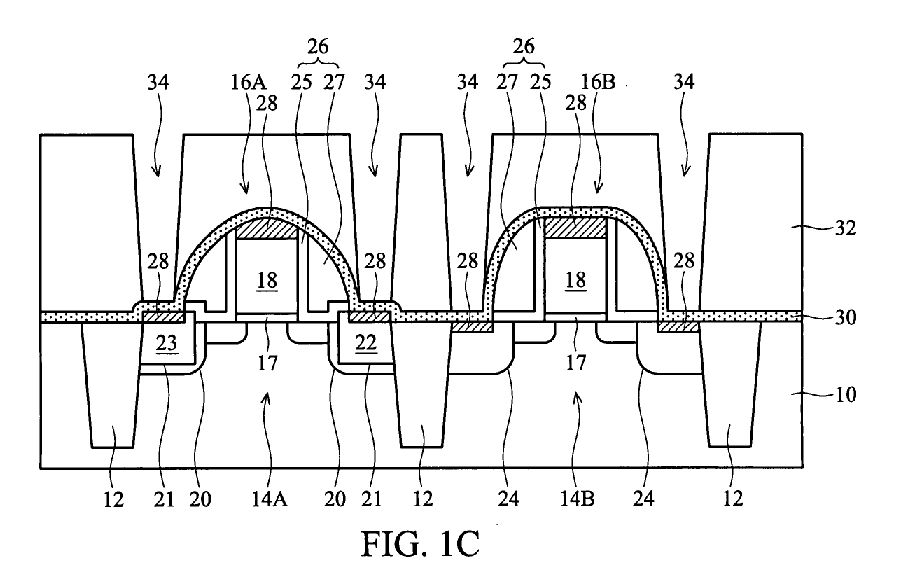

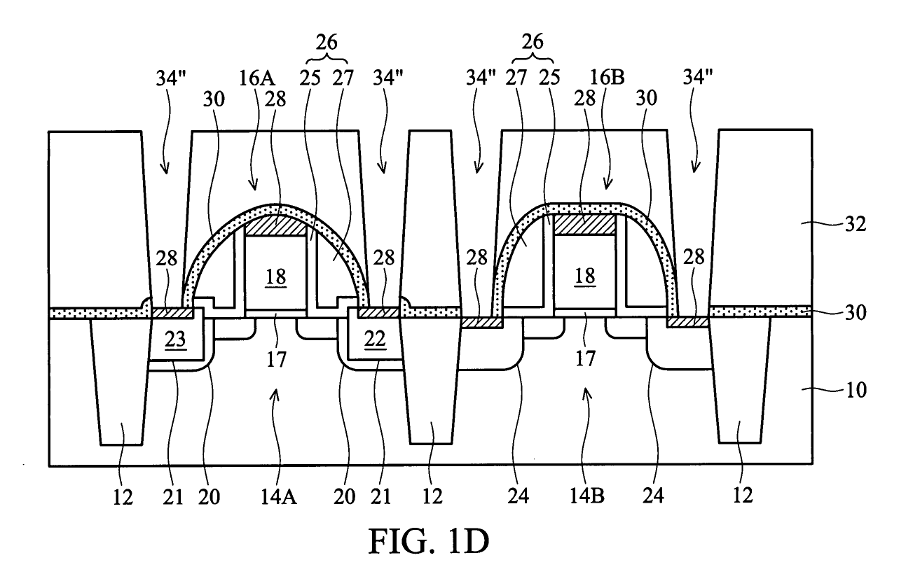

Herein, cross-sectional diagrams of FIGS. 1A to 1D illustrate an exemplary embodiment of a method of forming a strain enhanced CMOS architecture using an amorphous carbon film with tensile stress. Referring to FIG. 1A, a semiconductor substrate 10 comprises isolation structures 12 for isolating a first device region 14A and a second device region 14B. As will be described in the following disclosure in greater detail, the first device region 14A for forming a pMOS device refers to a pMOS device region 14A, and the second device region 14B for forming an nMOS device refers to an nMOS device region 14B. The nMOS and pMOS devices may be fabricated on a P-well and N-well structure, and may be fabricated directly onto or within the semiconductor substrate. In the present example, the isolation structure 12 between the nMOS and pMOS device may utilize isolation technology, such as local oxidation of silicon (LOCOS) and shallow trench isolation (STI).

The semiconductor substrate 10 is bulk silicon, but other commonly used materials and structures such as silicon on insulator (SOI) or a silicon layer overlying a bulk silicon germanium may also be used. Two gate structures 16A and 16B separated by the isolation structure 12 are formed on the semiconductor substrate 10 within the pMOS device region 14A and the nMOS device region 14B respectively. Each of the gate structures 16A and 16B includes a gate dielectric 17 patterned on the substrate 10, a gate electrode 18 patterned on the gate dielectric 17, and source/drain regions 20, 24 in the substrate 10 laterally adjacent to the gate electrode 18. The gate dielectric 17 may be formed of silicon oxide or a high-k dielectric material. The gate electrode 18 may be formed of amorphous polysilicon, doped polysilicon, metal, single crystalline silicon or other conductive materials.

On the pMOS device region 14A, impurities are implanted into the substrate 10 to form source/drain regions 20 (that may include doped extension regions), and recesses 21 are formed in the source/drain regions 20 by etching isotropically and/or anisotropically. Through epitaxial growth in the recesses 21, epitaxy regions 22 are therefore embedded in the source/drain regions 20. For example, SiGe epitaxy regions are formed in the pMOS device. The SiGe epitaxy regions will introduce a compressive stress in the channel region so that the pMOS device drive current will be enhanced. Whether a transistor is nMOS or pMOS will depend on the conductivity type of the substrate and the source/drain regions. For pMOS transistors, the source/drain regions will be p-type and the substrate will be n-type. For nMOS transistors, the source/drain regions will be n-type and the substrate will be p-type.

Through deposition and anisotropical etching processes, dielectric spacers 26 are formed on the sidewalls of the gate electrodes 18, respectively. The dielectric spacer 26 may be formed of oxide, nitride, oxynitride, or combinations thereof. For example, the dielectric spacer 26 includes an oxide liner 25 and a nitride layer 27. A silicidation process is then performed to form silicide regions 28 on exposed semiconductor materials, such as the epitaxy regions 22, gate electrodes 18 and source/drain regions 24. The silicide region 28 may be a metal silicide layer comprising metals such as titanium, cobalt, nickel, palladium, platinum, erbium, and the like.

In FIG. 1B, an amorphous carbon film 30 with tensile stress is deposited on the resulted structure as illustrated in FIG. 1A. The amorphous carbon film 30 acts not only a tensile stress capping film for introducing tensile strain into the nMOS device and enhancing its electron mobility, but also a contact etch stop layer (CESL) for controlling the end point and minimizing silicide loss during subsequent contact hole formation. The amorphous carbon film 30 may be formed by PVD, CVD or plasma assisted methods, such as using a high-density plasma chemical vapor deposition (HDP-CVD) system. The amorphous carbon film 30 has a tensile stress of 0˜10 Gpa, a dielectric constant of less than about 2.8 and a hydrogen-free property, thus improving device performance, reliability and yield. The amorphous carbon film 30 has a thickness from about 50 Angstroms to about 1000 Angstroms. The amorphous carbon film 30 may refer to undoped or fluorine doped amorphous carbon. For example using a plasma CVD method with a fluorine source target and a carbon source target such as graphite, at a temperature of from about 25° C. to about 400° C., a low dielectric constant fluorinated amorphous carbon film having a dielectric constant of approximately 2.0 to 2.4 is formed. The fluorinated amorphous carbon may have a fluorine concentration of from about 10 atomic weight % to about 60 atomic weight %.

In FIG. 1C, an interlayer dielectric layer 32 is blanket deposited on the amorphous carbon film 30. The interlayer dielectric layer 32 may be a silicon oxide containing layer formed of doped or undoped silicon oxide by a thermal CVD process or high-density plasma (HDP) process, e.g., undoped silicate glass (USG), phosphorous doped silicate glass (PSG) or borophosphosilicate glass (BPSG). Alternatively, the interlayer dielectric layer 32 may be formed of doped or P-doped spin-on-glass (SOG), PTEOS, or BPTEOS. Following planarization, e.g., chemical mechanical planarization (CMP) on the interlayer dielectric layer 32, a dielectric anti-reflective coating (DARC) or/and a bottom anti-reflectance coating (BARC) and a lithographically patterned photoresist layer are provided, which are omitted in the Figures for simplicity and clarity. A dry etching process is then carried out to form contact openings 34 that pass though the interlayer dielectric layer 32 and stop on the amorphous carbon film 30. Next, a dry etching process is further performed to remove the exposed portions of amorphous carbon film 30 and in-situ strip the patterned photoresist and the BARC layer so as to extend the contact openings 34″ to the silicide regions 28 positioned over the source/drain regions 20 and 24, as illustrated in FIG. 1D. It will be appreciated that contact openings may also be formed to expose the silicide region on the gate electrode.

Referring to FIG. 1C, in the step of etching the interlayer dielectric layer 32, plasma source gases C₄F₆ and/or C₄F₈ together with CF₄ are used. Alternatively, an etching chemistry such as CH₂F₂ together with O₂ and argon plasma source gases may be used. Referring to FIG. 1D, in the step of in-situ etching the photoresist layer, the BARC layer and amorphous carbon film 30, the amorphous carbon film 30 is removed simultaneously in a dry stripping process using a dry stripping chemistry of H₂ and O₂ together with CF₄ as plasma source gases, an RF power source of about 800 Watts to about 1200 Watts, a bias RF power of about 30 Watts to about 70 Watts and a plasma process pressure of less than about 50 mTorr. Advantageously, there is negligible loss of critical material layers underlying the amorphous carbon film 30, including silicide and/or oxide from adjacent isolation structures 12. The capability of stripping the amorphous carbon film 30 results in the unique process step that possibly strips the photoresist, BARC and contact etch stop layer simultaneously. Following the formation of the contact openings 34″, a conductive material, such as tungsten or metals, will backfill the contact openings 34″ to form contact plugs in the interlayer dielectric layer 32.

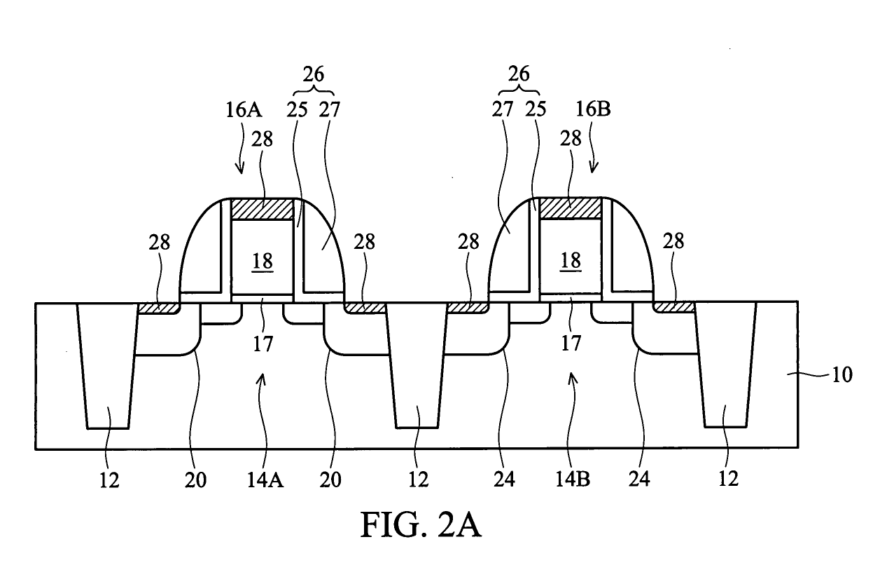

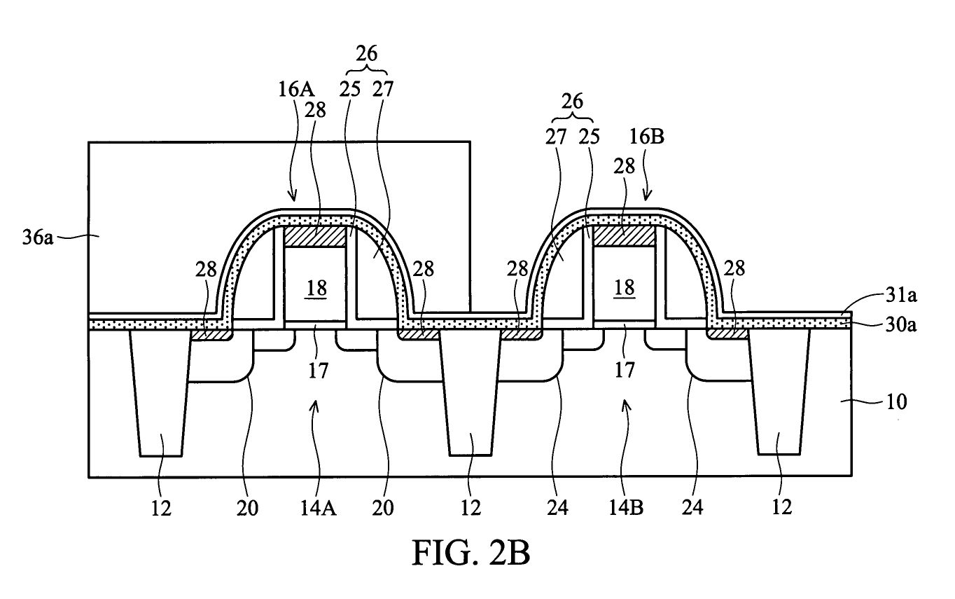

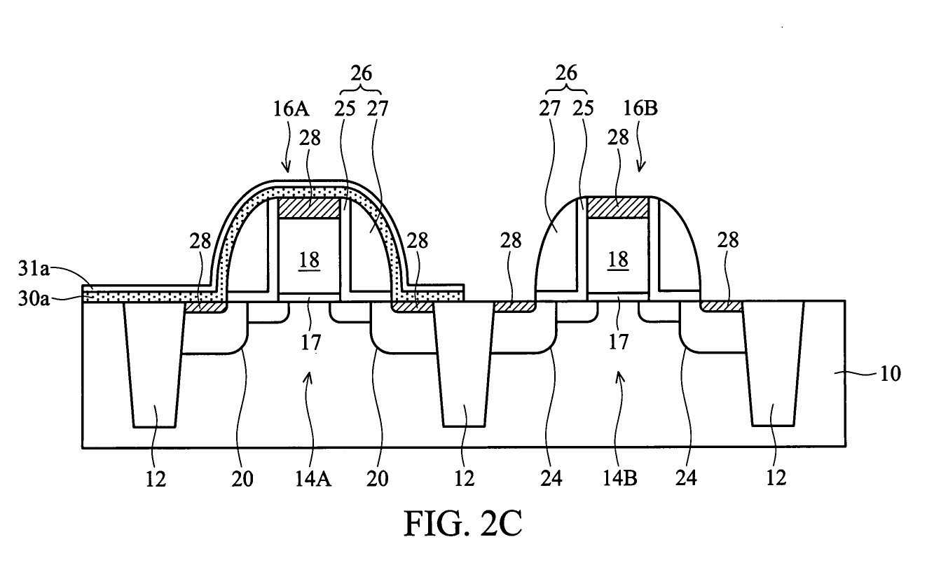

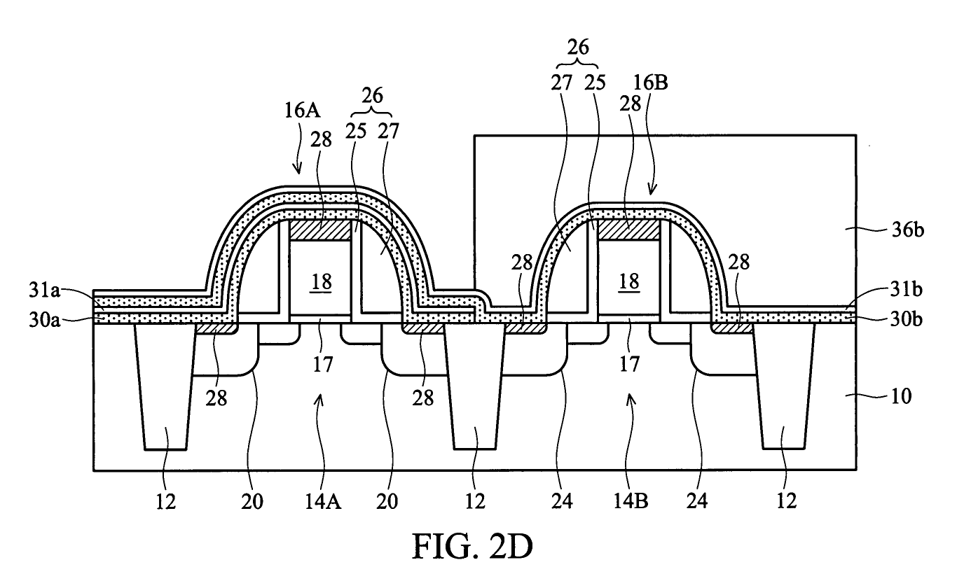

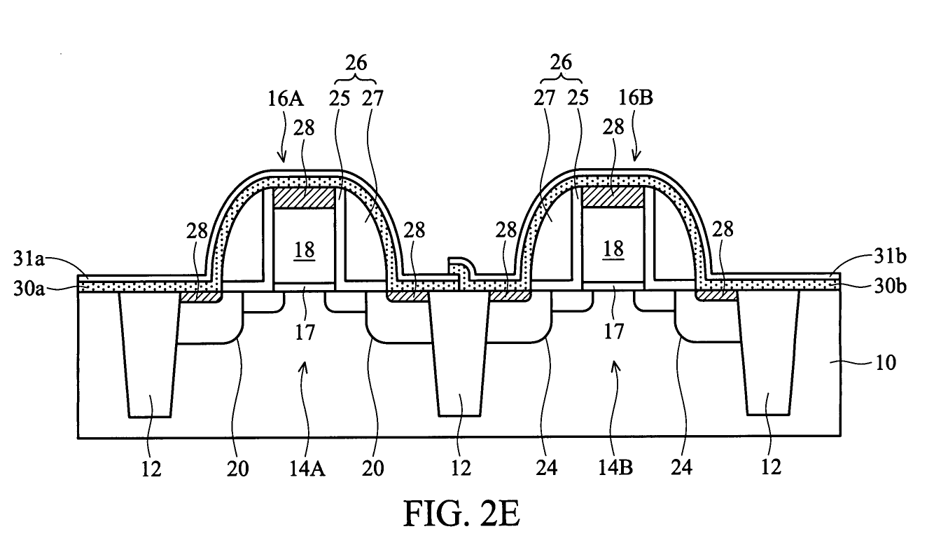

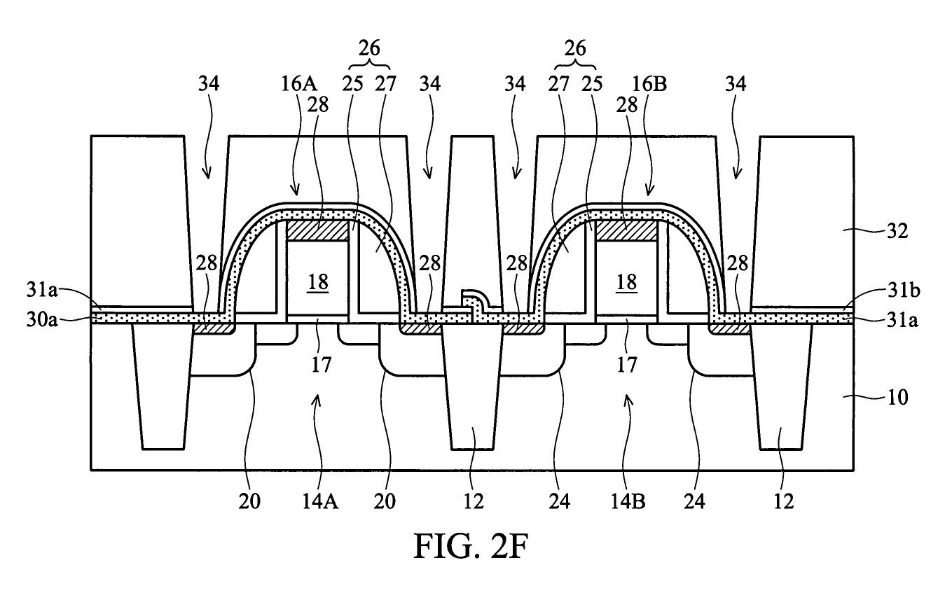

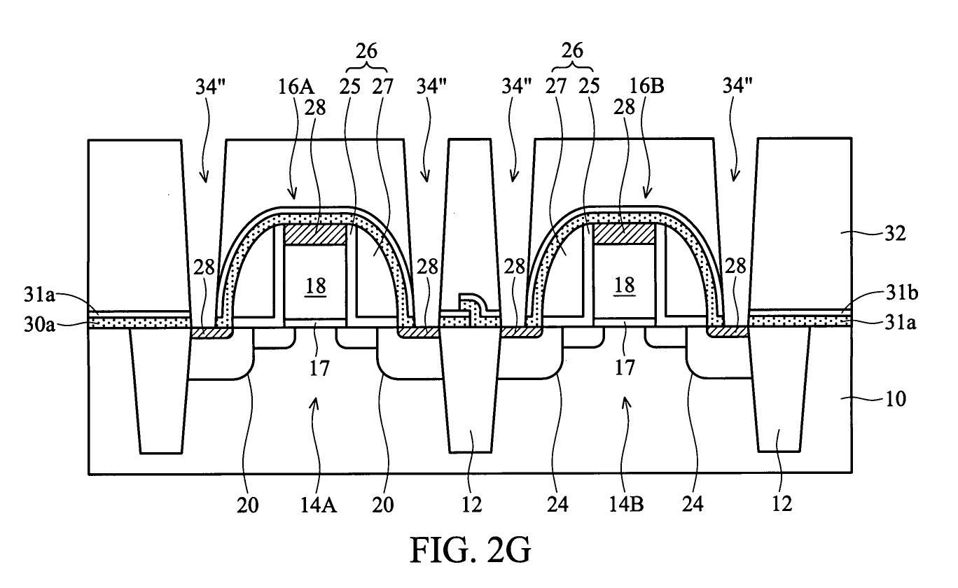

Cross-sectional diagrams of FIGS. 2A to 2G illustrate an exemplary embodiment of a method of forming a strain enhanced CMOS architecture using amorphous carbon films as a tensile stress capping film and a compressive stress capping film on the nMOS device and the pMOS device respectively. Explanation of the same or similar portions to the description in FIGS. 1A-1D is omitted herein.

In FIG. 2A, the semiconductor substrate 10 is provided with isolation structures 12 for isolating the pMOS device region 14A and the NMOS device region 14B. Two gate structures 16A and 16B are formed on the pMOS device region 14A and the NMOS device region 14B respectively. Each of the gate structures 16A and 16B includes a gate dielectric 17, a gate electrode 18, and source/drain regions 20,24 laterally adjacent to the gate electrode 18. The dielectric spacers 26, for example including an oxide liner 25 and a nitride layer 27, are formed on the sidewalls of the gate electrodes 18, respectively. A silicidation process is performed to form silicide regions 28 on exposed semiconductor materials, such as the source/drain regions 20 and 24 and gate electrodes 18.

In FIG. 2B, a first amorphous carbon film 30a with compressive stress is deposited on the resulted structure as illustrated in FIG. 2A. The first amorphous carbon film 30a acts a compressive stress capping film for introducing compressive strain into the pMOS device and enhancing its hole mobility. The first amorphous carbon film 30a also acts a contact etch stop layer (CESL) for controlling the end point and minimizing silicide loss during subsequent contact hole formation. The first amorphous carbon film 30a may be formed by PVD, CVD or plasma assisted methods, such as using a high-density plasma chemical vapor deposition (HDP-CVD) system. The first amorphous carbon film 30a has a compressive stress of 0˜10 Gpa, a dielectric constant of less than about 2.8 and a hydrogen-free property, thus improving device performance, reliability and yield. The first amorphous carbon film 30a has a thickness from about 50 Angstroms to about 1000 Angstroms. The first amorphous carbon film 30a may refer to undoped or fluorine doped amorphous carbon film.

Optionally, a first barrier layer 31a may be deposited on the first amorphous carbon film 30a for severing as an etch stop layer in a subsequent removal of photoresist. The first barrier layer 31a may be formed of oxide, oxynitride, nitride, carbide, or combinations thereof. Although the embodiment illustrates the first barrier layer 31a in the Figures, the present invention provides value when the first barrier layer 31a is omitted herein. A first photoresist layer 36a is coated on the substrate 10 and then lithographically patterned to cover the pMOS device region 14A.

In FIG. 2C, by the use of dry etching process with the first photoresist layer 36a as a mask, the exposed portions of the first barrier layer 31a and the first amorphous carbon film 30a are selectively removed from the uncovered nMOS device region 14B. The first photoresist layer 36a is then removed by dry ash or wet strip. In the selective removal of the first amorphous carbon film 30a from the uncovered nMOS device region 14B, O₂ optionally together with N₂ and CₓF_{y} are used as the etching gases in the dry etching process with a high selectivity (greater than about 10) to the underlying layers including silicon, oxide or silicide.

In FIG. 2D, a second amorphous carbon film 30b with tensile stress is deposited on the resulted structure as illustrated in FIG. 2C. The second amorphous carbon film 30b acts a tensile stress capping film for introducing tensile strain into the nMOS device and enhancing its electron mobility. The second amorphous carbon film 30b also acts a contact etch stop layer (CESL) for controlling the end point and minimizing silicide loss during subsequent contact hole formation. The second amorphous carbon film 30b may be formed by PVD, CVD or plasma assisted methods, such as using a high-density plasma chemical vapor deposition (HDP-CVD) system. The second amorphous carbon film 30b has a compressive stress of 0˜10 Gpa, a dielectric constant of less than about 2.8 and a hydrogen-free property, thus improving device performance, reliability and yield. The second amorphous carbon film 30b has a thickness from about 50 Angstroms to about 1000 Angstroms. The second amorphous carbon film 30b may refer to undoped or fluorine doped amorphous carbon film.

Optionally, a second barrier layer 31b may be deposited on the second amorphous carbon film 30b for serving as an etch stop layer in a subsequent removal of photoresist. The second barrier layer 31b may be formed of oxide, oxynitride, nitride, carbide, or combinations thereof. Although the embodiment illustrates the second barrier layer 31b in the Figures, the present invention provides value when the second barrier layer 31b is omitted herein. A second photoresist layer 36b is coated on the substrate 10 and then lithographically patterned to cover the nMOS device region 14B.

In FIG. 2E, by the use of dry etching process with-the second photoresist layer 36b as a mask, the exposed portions of the second barrier layer 31b and the second amorphous carbon film 30b are selectively removed from the uncovered pMOS device region 14A. The second photoresist layer 36b is then removed by dry ash or wet strip. In the selective removal of the second amorphous carbon film 30b from the uncovered pMOS device region 14A, O₂ optionally together with N₂ and CₓF_{y} are used as the etching gases in the dry etching process with a high selectivity (greater than about 10) to the underlying layers including silicon, oxide or silicide.

In FIG. 2F, an interlayer dielectric layer 32 is blanket deposited on the resulted structure as illustrated in FIG. 2E. Following planarization, e.g., CMP on the interlayer dielectric layer 32, a dielectric anti-reflective coating (DARC) or/and a bottom anti-reflectance coating (BARC) and a lithographically patterned photoresist layer are provided. A dry etching process is then carried out to form contact openings 34 that pass though the interlayer dielectric layer 32 and stop on the amorphous carbon films 30a and 30b. Next, a dry etching process is further performed to remove the amorphous carbon film 30 and in-situ strip the patterned photoresist and the BARC layer so as to extend the contact openings 34″ to the silicide regions 28 over the source/drain regions 20 and 24, as illustrated in FIG. 2G. It will be appreciated that contact openings may also be formed to expose silicide regions on the gate electrodes. Advantageously, in the step of in-situ etching the photoresist layer, the BARC layer and amorphous carbon films 30a and 30b, there is negligible loss of critical material layers underlying the amorphous carbon films 30a and 30b, such as silicide and/or oxide adjacent to isolation structures 12. The capability of stripping the amorphous carbon films 30a and 30b results in the unique process step that possibly strips the photoresist, BARC and contact etch stop layer simultaneously. Following the formation of the contact openings 34″, a conductive material, such as tungsten or metals, will backfill the contact openings 34″ to form contact plugs in the interlayer dielectric layer 32.

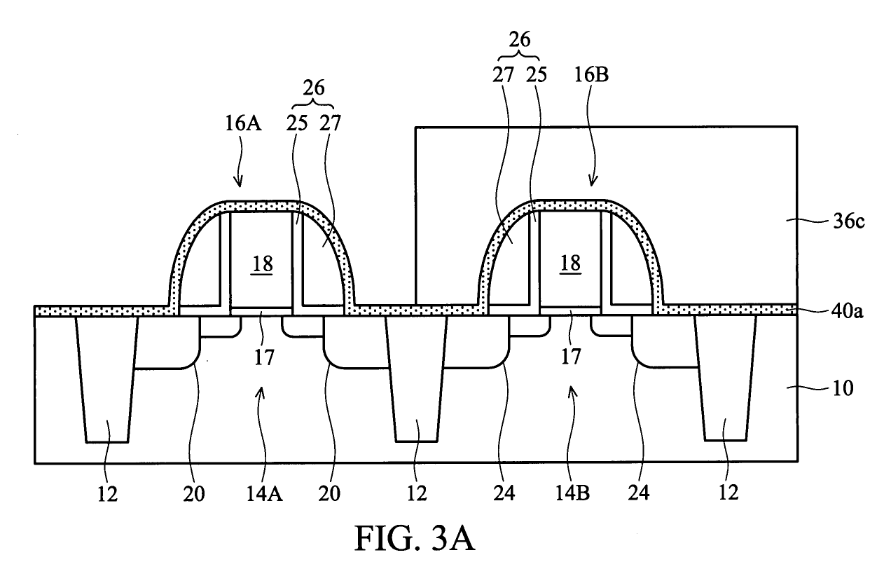

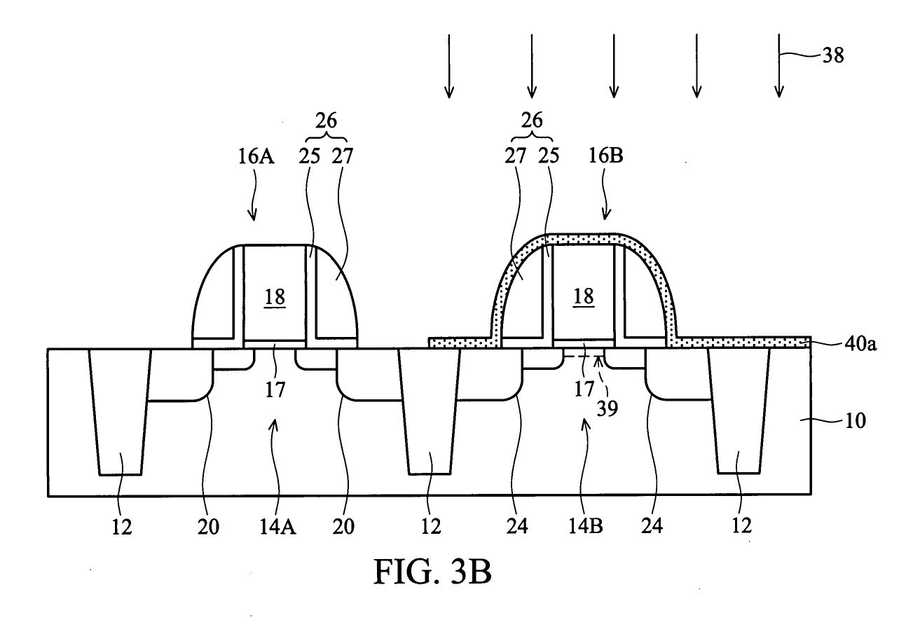

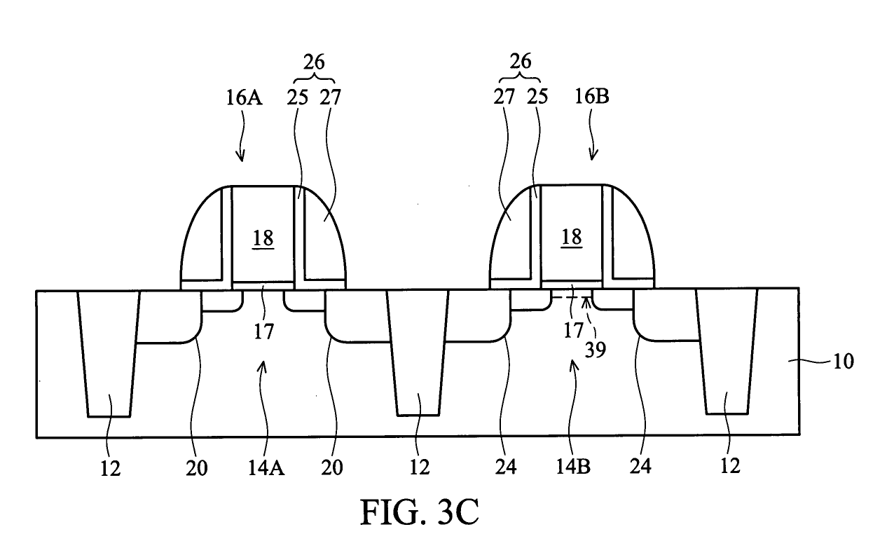

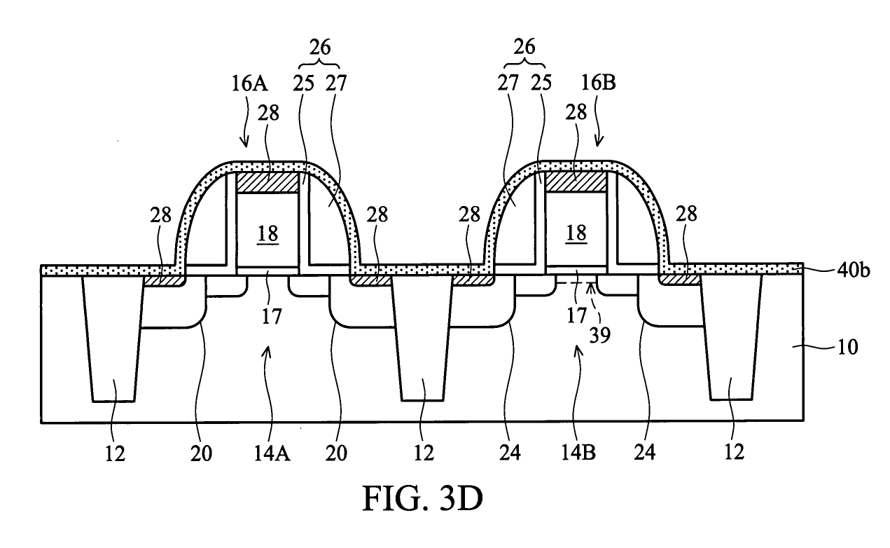

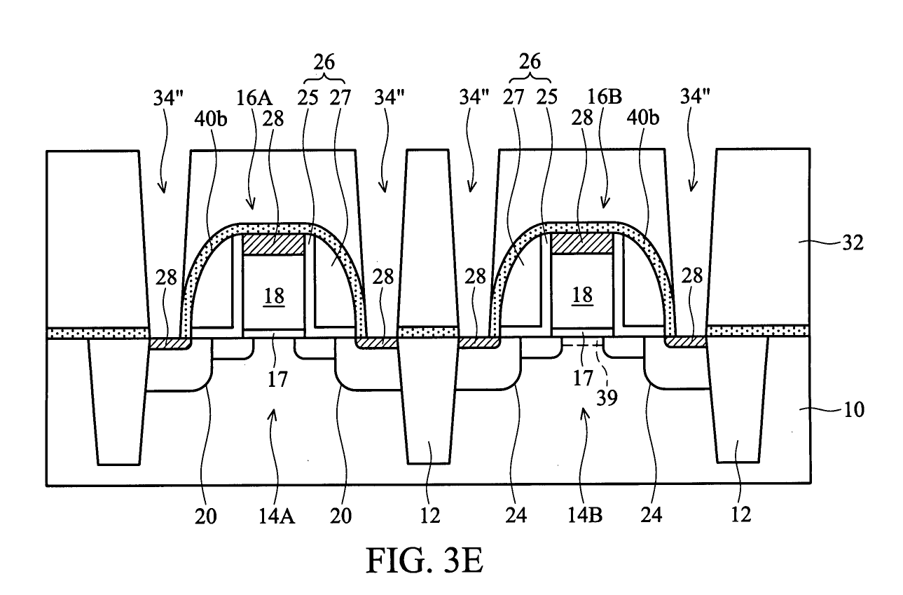

Cross-sectional diagrams of FIGS. 3A to 3E illustrate an exemplary embodiment of a method of forming a strain enhanced CMOS architecture using amorphous carbon films as an activation capping film and a tensile stress capping film on the nMOS device. Explanation of the same or similar portions to the description in FIGS. 1A-1D and FIGS. 2A-2G is omitted herein.

In FIG. 3A, the semiconductor substrate 10 is provided with isolation structures 12 for isolating the pMOS device region 14A and the nMOS device region 14B. Two gate structures 16A and 16B are formed on the pMOS device region 14A and the nMOS device region 14B respectively. Each of the gate structures 16A and 16B includes a gate dielectric 17, a gate electrode 18, and source/drain regions 20, 24 laterally adjacent to the gate electrode 18. The dielectric spacers 26, for example including an oxide liner 25 and a nitride layer 27, are formed on the sidewalls of the gate electrodes 18, respectively.

A first amorphous carbon film 40a with tensile stress is deposited on the resulted structure. The first amorphous carbon film 40a acts an activation capping film in subsequent annealing process. The first amorphous carbon film 40a may be formed by PVD, CVD or plasma assisted methods, such as using a high-density plasma chemical vapor deposition (HDP-CVD) system. The first amorphous carbon film 40a has a compressive stress of 0˜10 Gpa, a dielectric constant of less than about 2.8 and a hydrogen-free property. The first amorphous carbon film 40a has a thickness from about 50 Angstroms to about 1000 Angstroms. The first amorphous carbon film 40a may refer to undoped or fluorine doped amorphous carbon film. A photoresist layer 36c is coated on the substrate 10 and then lithographically patterned to cover the nMOS device region 14B.

In FIG. 3B, by the use of dry etching process with the photoresist layer 36c as a mask, the exposed portions of the first amorphous carbon film 40a is selectively removed from the uncovered pMOS device region 14A. The photoresist layer 36c is then removed by dry ash or wet strip. In the selective removal of the first amorphous carbon film 40a, O₂ optionally together with N₂ and CₓF_{y} are used as the etching gases in the dry etching process with a high selectivity (greater than about 10) to the underlying layers. Thereafter, an activation anneal 38 is performed on the resulted structure to introduce tensile stress across the channel region of the nMOS device, achieving high tensile stress in the channel region 39. The activation anneal 38 may be performed at a furnace temperature of 800° C. to 1100° C., using a rapid thermal anneal or a spike anneal. The first amorphous carbon film 40a is then removed from the nMOS device region 14B as illustrated in FIG. 3C.

In FIG. 3D, a silicidation process is performed to form silicide regions 28 on exposed semiconductor materials, such as the source/drain regions 20 and 24 and gate electrodes 18. The silicide regions 28 may comprise metals such as titanium, cobalt, nickel, palladium, platinum, erbium, and the like. Next, a second amorphous carbon film 40b with tensile stress is deposited on the resulted structure. The second amorphous carbon film 40b acts not only a tensile stress capping film for introducing tensile strain into the nMOS device and enhancing its electron mobility, but also a contact etch stop layer (CESL) for controlling the end point and minimizing silicide loss during subsequent contact hole formation. The second amorphous carbon film 40b may be formed by PVD, CVD or plasma assisted methods, such as using a high-density plasma chemical vapor deposition (HDP-CVD) system. The second amorphous carbon film 40b has a tensile stress of 0˜10 Gpa, a dielectric constant of less than about 2.8 and a hydrogen-free property, thus improving device performance, reliability and yield. The second amorphous carbon film 40b has a thickness from about 50 Angstroms to about 1000 Angstroms. The second amorphous carbon film 40b may refer to undoped or fluorine doped amorphous carbon film.

In FIG. 3E, an interlayer dielectric layer 32 is blanket deposited on the resulted structure as illustrated in FIG. 3D. Following planarization, e.g., CMP on the interlayer dielectric layer 32, a dielectric anti-reflective coating (DARC) or/and a bottom anti-reflectance coating (BARC) and a lithographically patterned photoresist layer are provided. A dry etching process is then carried out to form openings that pass though the interlayer dielectric layer 32 and stop on the second amorphous carbon film 40b. Next, a dry etching process is further performed to remove the second amorphous carbon film 40b and in-situ strip the patterned photoresist and the BARC layer so as to extend the contact openings 34″ to the silicide regions 28 over the source/drain regions 20 and 24. It will be appreciated that contact openings may also be formed to expose silicide regions on the gate electrodes.

Although the present invention has been described in its preferred embodiments, it is not intended to limit the invention to the precise embodiments disclosed herein. Those skilled in this technology can still make various alterations and modifications without departing from the scope and spirit of this invention. Therefore, the scope of the present invention shall be defined and protected by the following claims and their equivalents.

What is claimed is:

1. A semiconductor device, comprising:
a semiconductor substrate having a pMOS device region and an nMOS device region;
a first gate structure overlying said pMOS device region and a second gate structure overlying said nMOS device region, wherein each of said first gate structure and said second gate structure comprises a gate electrode overlying said semiconductor substrate and a source/drain region in said semiconductor substrate laterally adjacent to said gate electrode;
silicide regions on said gate electrodes and said source/drain regions of said first gate structure and said second gate structure respectively;
an amorphous carbon film with tensile stress overlying said first gate structure, said second gate structure and said silicide regions; and
a dielectric layer overlying said amorphous carbon film and comprising contact holes passing through said dielectric layer and said amorphous carbon film to expose said silicide regions on said source/drain regions of said first gate structure and said second gate structure respectively.

2. The semiconductor device of claim 1, further comprising an epitaxy region in a recess of said source/drain region of said first gate structure.

3. The semiconductor device of claim 2, wherein said silicide region is formed on said epitaxy region.

4. The semiconductor device of claim 2, wherein said epitaxy region comprises SiGe.

5. The semiconductor device of claim 1, wherein said amorphous carbon film comprises fluorinated amorphous carbon (a-C:F).

6. The semiconductor device of claim 1, wherein said amorphous carbon film serves as a stress capping layer and a contact etch stop layer.

7. A semiconductor device, comprising:
a semiconductor substrate having a pMOS device region and an nMOS device region;
a first gate structure overlying said pMOS device region and a second gate structure overlying said nMOS device region, wherein each of said first gate structure and said second gate structure comprises a gate electrode overlying said semiconductor substrate and a source/drain region in said semiconductor substrate laterally adjacent to said gate electrode;
silicide regions on said gate electrodes and said source/drain regions of said first gate structure and said second gate structure respectively;
a first amorphous carbon film with compressive stress overlying said first gate structure and said silicide regions on said pMOS device region;
a second amorphous carbon film with tensile stress overlying said second gate structure and said silicide regions on said nMOS device region; and
a dielectric layer overlying said first amorphous carbon film and said second amorphous carbon film and comprising contact holes passing through said dielectric layer, said first amorphous carbon film and said second amorphous carbon film to expose said silicide regions on said source/drain regions of said first gate structure and said second gate structure respectively.

8. The semiconductor device of claim 7, wherein said amorphous carbon film comprises fluorinated amorphous carbon (a-C:F).

9. The semiconductor device of claim 7, wherein each of said first amorphous carbon film and said second amorphous carbon film serves as a stress capping layer and a contact etch stop layer.

10. The semiconductor device of claim 7, further comprising:
a first barrier layer between said first amorphous carbon film and said dielectric layer on said pMOS device region; and
a second barrier layer between said second amorphous carbon film and said dielectric layer on said nMOS device region.

11. A method of forming a semiconductor device, comprising:
providing a semiconductor substrate having a pMOS device region and an nMOS device region;
forming a first gate structure overlying said pMOS device region and a second gate structure overlying said nMOS device region, wherein each of said first gate structure and said second gate structure comprises a gate electrode overlying said semiconductor substrate and a source/drain region in said semiconductor substrate laterally adjacent to said gate electrode;
forming silicide regions on said gate electrodes and said source/drain regions of said first gate structure and said second gate structure respectively;
forming an amorphous carbon film with tensile stress on said semiconductor substrate to cover said first gate structure, said second gate structure and said silicide regions;
forming a dielectric layer overlying said amorphous carbon film; and
forming contact holes passing through said dielectric layer and said amorphous carbon film to expose said silicide regions on said source/drain regions of said first gate structure and said second gate structure respectively.

12. The method of claim 11, before forming silicide regions on said gate electrode and said source/drain region of said first gate structure, further comprising:
forming a recess in said source/drain region of said first gate structure; and
forming an epitaxy region in said recess of said source/drain region of said first gate structure.

13. The method of claim 12, wherein said epitaxy region comprises SiGe.

14. The method of claim 11, wherein said amorphous carbon film comprises fluorinated amorphous carbon (a-C:F).

15. A method of forming a semiconductor device, comprising:
providing a semiconductor substrate having a pMOS device region and an nMOS device region;
forming a first gate structure overlying said pMOS device region and a second gate structure overlying said nMOS device region, wherein each of said first gate structure and said second gate structure comprises a gate electrode overlying said semiconductor substrate and a source/drain region in said semiconductor substrate laterally adjacent to said gate electrode;
forming silicide regions on said gate electrodes and said source/drain regions of said first gate structure and said second gate structure respectively;
forming a first amorphous carbon film with compressive stress covering said first gate structure and said silicide region on said pMOS device region;
forming a second amorphous carbon film with tensile stress covering said second gate structure and said silicide region on said nMOS device region;
forming a dielectric layer overlying said first amorphous carbon film and said second amorphous carbon film; and
forming contact holes passing through said dielectric layer, said first amorphous carbon film and said second amorphous carbon film to expose said silicide regions on said source/drain regions of said first gate structure and said second gate structure respectively.

16. The method of claim 15, wherein said amorphous carbon film comprises fluorinated amorphous carbon (a-C:F).

17. The method of claim 15, before forming said dielectric layer, further comprising:
forming a first barrier layer on said first amorphous carbon films on said pMOS device region.

18. The method of claim 15, before forming said dielectric layer, further comprising:
forming a second barrier layer on said second amorphous carbon films on said NMOS device region.

19. A method of forming a semiconductor device, comprising:
providing a semiconductor substrate having a pMOS device region and an nMOS device region;
forming a first gate structure overlying said pMOS device region and a second gate structure overlying said nMOS device region, wherein each of said first gate structure and said second gate structure comprises a gate electrode overlying said semiconductor substrate and a source/drain region in said semiconductor substrate laterally adjacent to said gate electrode;
forming a first amorphous carbon film with tensile stress to cover said second gate structure on said nMOS device region;
performing an activation anneal process to achieve tensile stress in a channel region of said second gate structure;
removing said first amorphous carbon film;
forming silicide regions on exposed portions of said gate electrodes and said source/drain regions of said first gate structure and said second gate structure respectively;
forming a second amorphous carbon film with tensile stress on said semiconductor substrate to cover said first gate structure, said second gate structure and said silicide regions;
forming a dielectric layer overlying said second amorphous carbon film; and
forming contact holes passing through said dielectric layer and said second amorphous carbon film to expose said silicide regions on said source/drain regions of said first gate structure and said second gate structure respectively.

20. The method of claim 19, wherein said amorphous carbon film comprises fluorinated amorphous carbon (a-C:F).
